(19) United States
(12) Patent Application Publication
(10) Pub. No.: US 2014/0070830 A1
(43) Pub. Date: Mar. 13, 2014

(54) MEASURING DEVICE, MEASURING METHOD, AND ELEMENT MANUFACTURING METHOD INCLUDING MEASURING METHOD

(71) Applicant: Sumitomo Electric Industries, Ltd., Osaka-shi (JP)

(72) Inventors: Mitsuhiko Sakai, Osaka-shi (JP); Takeyoshi Masuda, Osaka-shi (JP); Kenji Hiratsuka, Osaka-shi (JP)

(73) Assignee: Sumitomo Electric Industries, Ltd., Osaka-shi (JP)

(21) Appl. No.: 13/951,724

(22) Filed: Jul. 26, 2013

Related U.S. Application Data
(60) Provisional application No. 61/698,260, filed on Sep. 7, 2012.

(30) Foreign Application Priority Data
Sep. 7, 2012 (JP) 2012-196977

(51) Int. Cl. G01R 1/067

(52) U.S. Cl. CPC G01R 1/06777
USPC 324/754.01; 324/755.01

(57) ABSTRACT

A measuring device includes: a probe applying a voltage to an electrode of an element; and a supplying member supplying an insulating liquid to a contact portion between the electrode and the probe via a surface of the probe. Accordingly, the insulating liquid can be securely supplied to the contact portion between the electrode and the probe via the surface of the probe positioned relative to the electrode.

### BACKGROUND OF THE INVENTION

1. Field of the Invention

The present invention relates to a measuring device, a measuring method, and an element manufacturing method including the measuring method. In particular, the present invention relates to a measuring device, a measuring method, and an element manufacturing method including the measuring method, each of which is directed to breakdown voltage measurement in which a high voltage is applied to an electrode of an element.

2. Description of the Background Art

A semiconductor device capable of handling a large amount of electric power is generally called “power device”. In order to handle a large amount of electric power, the semiconductor device is expected to achieve high breakdown voltage, low loss, utilization under a high temperature environment, and the like. Accordingly, the breakdown voltage is one of important evaluation criteria for such a power device.

The breakdown voltage measurement can be performed before an element separating step, or can be performed after the element separating step. For inspection efficiency, it is desirable to perform the breakdown voltage measurement before the element separating step.

In order to perform the breakdown voltage measurement onto the elements that are in the form of a wafer before the element separation, a plurality of probes need to make contact with electrodes of the elements for the purpose of the measurement. During the breakdown voltage measurement on this occasion, a high voltage of several hundred volts or more needs to be applied between the probes. Accordingly, aerial discharge takes place due to moisture on an element surface, with the result that an element is destroyed before reaching the designed breakdown voltage, disadvantageously.

In order to suppress such aerial discharge, Japanese Patent Laying-Open No. 59-3943 proposes a method for protecting whole or part of an element surface using an insulating resin film, for example. However, in the method for protecting the element surface using the insulating resin film, the resin film needs to be penetrated by a probe during breakdown voltage measurement. This provides a risk of damaging an element. Moreover, there is such a concern that the probe becomes quickly worn out.

To address this, Japanese Patent Laying-Open No. 2003-100819 proposes a method for performing measurement while soaking an element surface in an insulating solution. However, there is such a risk that the insulating solution is vaporized during the measurement. In addition, when the element surface is soaked in a large amount of insulating solution in order to prevent vaporization of the insulating solution during the measurement, measurement speed needs to be slower than that in normal measurement so as to prevent spilling of the insulating solution.

In view of this, Japanese Patent No. 4482061 proposes a breakdown voltage measurement method in which measurement is performed after ejecting an insulating liquid onto a portion of an element surface to cover it. Also, a breakdown voltage measuring device is disclosed which includes an insulating liquid ejecting unit for ejecting the insulating liquid.

### SUMMARY OF THE INVENTION

The breakdown voltage measuring device described in Japanese Patent No. 4482061 includes the insulating liquid ejecting unit, which is a member separated from the probe. Accordingly, a relative position relation is deviated between each of the probe and the insulating liquid ejecting unit and an electrode of each of a plurality of elements formed on a semiconductor wafer, unless the semiconductor wafer is precisely aligned. This makes it difficult to securely insulate a contact portion between the probe and the electrode.

The present invention has been made to solve the foregoing problem. The present invention has a main object to provide a measuring device, a measuring method, and a manufacturing method that employs the measuring device, so as to securely cover a contact portion between an electrode and a probe with an insulating liquid.

A measuring device according to the present invention includes: a probe applying a voltage to an electrode of an element; and a supplying member supplying an insulating liquid to a contact portion between the electrode and the probe via a surface of the probe.

Accordingly, the insulating liquid can be securely supplied to the contact portion between the electrode and the probe via the surface of the probe positioned relative to the electrode.

A measuring method according to the present invention includes the steps of: preparing a wafer provided with an element including an electrode; bringing the electrode of the element and a probe into contact with each other; and measuring an element characteristic by flowing an electric current between the probe and the electrode with an insulating liquid being supplied to a contact portion between the electrode and the probe via a surface of the probe. Thus, in the measuring method according to the present invention, the insulating liquid is supplied to the contact portion via the surface of the probe. Hence, the insulating liquid can be securely supplied to the contact portion by positioning the probe relative to the electrode.

According to the present invention, there can be provided a measuring device, a measuring method, and a manufacturing method so as to securely cover a contact portion between an electrode and a probe with an insulating liquid.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic view of a measuring device of a first embodiment.

FIG. 2 is a flowchart showing a measuring method in the first embodiment.

FIG. 3 is a schematic view showing a retaining portion in the first embodiment.

FIG. 4 shows a modification of FIG. 3.

FIG. 5 shows another modification of FIG. 3.

FIG. 6 shows still another modification of FIG. 3.

FIG. 7 is a schematic view of a measuring device in a second embodiment.

### DESCRIPTION OF THE PREFERRED EMBODIMENTS

The following describes embodiments of the present invention with reference to figures. It should be noted that in the below-mentioned figures, the same or corresponding portions are given the same reference characters and are not described repeatedly.

### First Embodiment

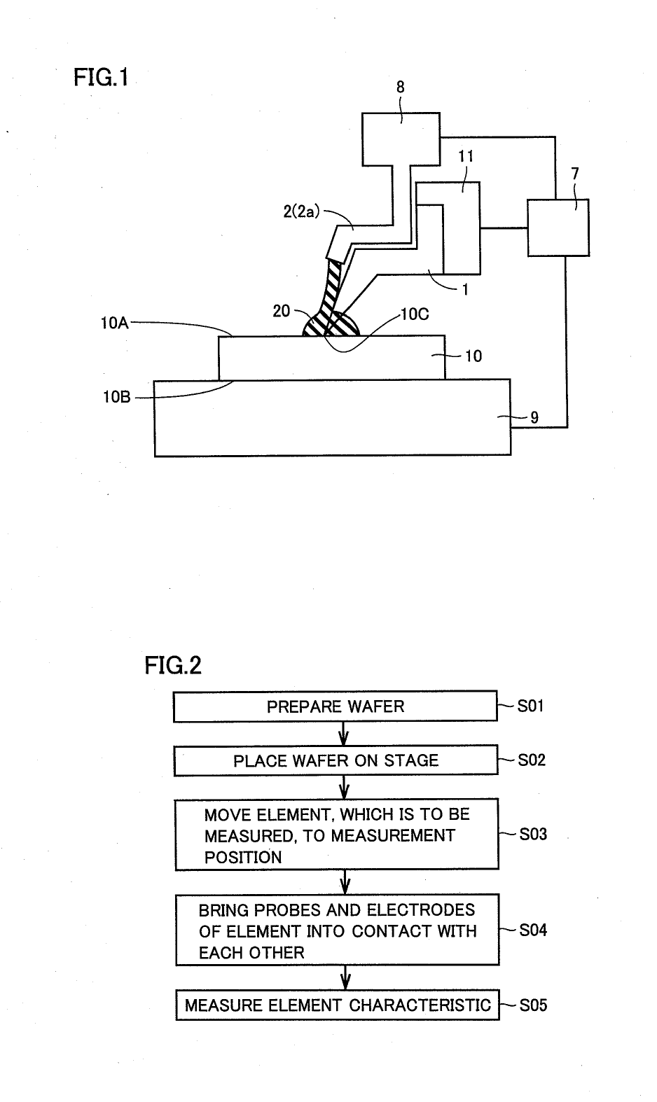

Referring to FIG. 1, the following describes a measuring device according to a first embodiment of the present invention. The measuring device according to the present embodiment is a device that measures an electric characteristic of each of elements that are in the form of a wafer 10 before an element separating step. The measuring device includes: probes 1 that apply voltage to electrodes of the element (not shown); and a supplying member 2 that supplies insulating liquid 20 to a contact portion 10C between each of the electrodes and each of probes 1 via a surface of probe 1.

In the present embodiment, the elements are a plurality of IGBTs (Insulated Gate Bipolar Transistor) formed on wafer 10. Each of the IGBTs has an emitter electrode and a gate electrode at the main surface 10A side of wafer 10, and has a collector electrode at the backside surface 10B side. Backside surface 10B is connected to a stage 9, so that wafer 10 is movably held. For example, wafer 10 is held by suctioning backside surface 10B to stage 9. Stage 9 has a surface that faces backside surface 10B and that has an electrically conductive member. When wafer 10 is placed on stage 9 such that backside surface 10B and the surface of stage 9 face each other, the collector electrode of each IGBT formed on wafer 10 is electrically connected to stage 9. Stage 9 is connected to a wafer position control unit, a voltage applying unit, and a current measuring unit in a control unit 7.

Probes 1 are configured to make contact with the emitter electrode and the gate electrode formed at the main surface 10A side of wafer 10, thereby achieving electric connection with the electrodes. In the measuring device according to the present embodiment, two probes 1 are respectively connected to the emitter electrode and the gate electrode. Two probes 1 are held by, for example, a base (not shown) via a holder 11. Further, two probes 1 are connected to control unit 7. The material and shape of each probe 1 may be appropriately configured to achieve a low-resistance contact with an electrode.

Supplying member 2 is attached to probe 1. Supplying member 2 is, for example, fixed to holder 11. Further, supplying member 2 is connected to a tank 8 that contains an insulating liquid 20 therein. Insulating liquid 20 flowing from tank 8 is ejected from an ejection nozzle 2a of supplying member 2 to the surface of probe 1 through an opening/closing member such as an electromagnetic valve, for example. Ejection nozzle 2a may be provided to be capable of supplying insulating liquid 20 to the surface of probe 1 at a predetermined distance and a predetermined height from the tip of probe 1, for example. With this, when probes 1 and the electrodes are brought into contact with one another, each probe 1 can be covered with insulating liquid 20 in a range from the surface of probe 1 to contact portion 10C. Supplying member 2 is connected to control unit 7, and ejects insulating liquid 20 at an amount and a timing both adjusted by control unit 7 controlling an operation of the opening/closing member, for example.

Insulating liquid 20 is a liquid having an electric insulation property. Here, the expression “having an electric insulation property” is intended to mean “having a dielectric strength higher than that of atmospheric air”. Insulating liquid 20 may be, for example, a fluorine-based inert liquid. Fluorinert provided by Sumitomo 3M, which is a fluorine-based inert liquid, has a dielectric strength of 35 kV or more per 2.54 mm gap, i.e., has a dielectric strength four times or more as high as that of the atmospheric air.

Control unit 7 is connected to probe 1, supplying member 2, and stage 9, and is configured to be capable of controlling these. Specifically, control unit 7 controls a position of stage 9. Further, control unit 7 applies a predetermined voltage between two selected from the electrodes (the emitter electrode, the gate electrode, and the collector electrode) of the IGBT via probe 1 and stage 9. On this occasion, control unit 7 measures a leakage current between the two electrodes thus fed with the voltage.

As described above, in the measuring device according to the present embodiment, supplying member 2 supplies insulating liquid 20 from ejection nozzle 2a to contact portion 10C between each probe 1 and each electrode via the surface of probe 1. Accordingly, contact portion 10C can be securely covered with insulating liquid 20.

Referring to FIG. 1 and FIG. 2, the following describes a measuring method according to the present embodiment. The measuring method according to the present embodiment includes the steps of: preparing a wafer 10 provided with elements (IGBT) including electrodes; bringing the electrodes of the elements and probes 1 into contact with one another; and measuring an element characteristic by applying a voltage between the electrodes with a contact portion 10C between each electrode and each probe 1 being supplied with an insulating liquid 20 via a surface of probe 1.

First, wafer 10 is prepared which is provided with elements including electrodes (S01). In the present embodiment, each of the elements formed on wafer 10 is an IGBT. An emitter electrode and a gate electrode are formed at the main surface 10A side of wafer 10. A collector electrode is formed at the backside surface 10B side of wafer 10.

Next, wafer 10 thus prepared is placed on stage 9 of the above-described measuring device according to the present embodiment (S02). In this step (S02), wafer 10 is placed on stage 9 such that backside surface 10B of wafer 10 faces the surface of stage 9. Accordingly, each of the collector electrodes of the plurality of IGBTs formed on wafer 10 is electrically connected to the surface of stage 9. Further, on this occasion, alignment adjustment of wafer 10 is performed.

Next, an IGBT to be measured among the plurality of IGBTs formed on wafer 10 is moved to a measurement position (S03). Specifically, control unit 7 moves stage 9 in a plane (XY plane) parallel to the surface of wafer 10, whereby the IGBT to be measured is moved to the measurement position.

Next, probes 1 are respectively brought into contact with the emitter electrode and the gate electrode of the IGBT formed on wafer 10 (S04). In this step (S04), stage 9 is moved to respectively bring the emitter electrode and the gate electrode of one IGBT, which is selected from the plurality of IGBTs formed on wafer 10, into contact with two probes 1 fixed to the base. Specifically, after moving it to the measurement position, stage 9 is moved in a direction (Z axis direction) perpendicular to the surface of wafer 10 so as to bring the electrodes of the IGBT to be measured and probes 1 into contact with one another. The position relation between two probes 1 is determined in advance based on the element shape of the IGBT, and is maintained. Further, the movement of stage 9 is controlled by control unit 7. For the plurality of IGBTs on wafer 10, control unit 7 may previously store the coordinates of an IGBT to be measured, the order of measurement, and a feed rate of probes 1, for example. With step (S02) and step (S04), each electrode of the IGBT to be measured is electrically connected to control unit 7, which applies a voltage to measure electric current. It should be noted that each probe 1 may be moved to change the relative position between stage 9 and probe 1.

In the measuring method according to the present embodiment, there is provided a step (S14) of supplying insulating liquid 20 to contact portion 10C via the surface of each probe 1 after probes 1 and the electrodes are brought into contact with one another in step (S04). In doing so, control unit 7 controls a timing at which insulating liquid 20 is supplied from ejection nozzle 2a of supplying member 2 to the surface of probe 1. For example, control unit 7 may make determination as to the contact between each of probes 1 and each of the electrodes based on the position information of stage 9, and thereafter may cause supplying member 2 to eject a predetermined amount of insulating liquid 20 from ejection nozzle 2a onto the surface of probe 1. Insulating liquid 20 covers probe 1 in a range from the surface of probe 1, onto which insulating liquid 20 has been ejected from ejection nozzle 2a, to the tip of probe 1. By the tip of probe 1 being in contact with the electrode, insulating liquid 20 is supplied to contact portion 10C. In doing so, the amount of insulating liquid 20 may be set at an amount by which aerial discharge can be prevented in a measuring step (S05) to be performed next. Specifically, the amount of insulating liquid 20 may be set at an amount by which insulating liquid 20 can cover the IGBT's region having no insulating film formed thereon (such as an electrode pad portion exposed due to formation of an opening in the insulating film). As a result, in this step (S14), contact portion 10C between each of probes 1 and each of the emitter electrode and the gate electrode can be securely covered with insulating liquid 20.

Next, with insulating liquid 20 being thus supplied to contact portion 10C between each of probes 1 and each of the electrodes, a voltage is applied between the electrodes so as to measure the element characteristic (S05). In this step (S05), a predetermined voltage is applied between two selected from the emitter electrode, the gate electrode, and the collector electrode of the IGBT, and an electric current flowing on this occasion is measured. For example, by establishing a short circuit between the emitter electrode and the gate electrode, applying a voltage between the emitter electrode and the collector electrode, and measuring a flowing electric current, breakdown voltage between the emitter and the collector is evaluated.

When the measurement for one IGBT is finished, control unit 7 moves stage 9 so as to separate probes 1 from the electrodes. Thereafter, until completion of measurement for all the IGBTs to be measured among those formed on wafer 10, step (S03), step (S04), step (S14), and step (S05) are performed repeatedly.

As described above, in the measuring method according to the present embodiment, contact portion 10C between each of probes 1 and each of the electrodes can be securely covered by supplying insulating liquid 20 to contact portion 10C via the surface of probe 1. Further, probe 1 can be also covered with insulating liquid 20 up to its portion located at a predetermined height from contact portion 10C. Further, the measuring method according to the present embodiment can be applied to an element characteristic evaluating step in a method for manufacturing an IGBT. For example, in the method for manufacturing the IGBT, an evaluating step may be performed using the measuring method according to the present embodiment as illustrated in FIG. 2, after performing a processing step of forming each structure of the IGBT on the wafer.

In the present embodiment, control unit 7 may cause ejection of a predetermined amount of insulating liquid 20 from ejection nozzle 2a of supplying member 2 to the surface of each probe 1 before detecting the contact between each of probes 1 and each of the electrodes. For example, insulating liquid 20 may be ejected from ejection nozzle 2a onto the surface of probe 1 while moving stage 9 to place, in the measurement position, an IGBT to be measured next among the plurality of IGBTs formed on wafer 10. In this way, it takes a shorter time for insulating liquid 20 to reach contact portion 10C after bringing probes 1 and the electrodes into contact with one another, as compared with a case where insulating liquid 20 is ejected onto the surface of each probe 1 after bringing probes 1 and the electrodes into contact with one another.

Further, control unit 7 may cause ejection of a predetermined amount of insulating liquid 20 from ejection nozzle 2a of supplying member 2 to the surface of probe 1 before detecting the contact between each of probes 1 and each of the electrodes and insulating liquid 20 may drip onto the element via the surface of each probe 1 after the alignment of the measurement position (step S03) and before bringing probes 1 and the electrodes into contact with one another (step S04) (for example, during the movement of stage 9 in the Z axis direction). Insulating liquid 20 drips from each of probes 1, and therefore, also in this case, can be securely supplied to the region at which each of probes 1 and each of the electrodes are in contact with each other. Further, as compared with the case where insulating liquid 20 is supplied after they are brought into contact with each other, insulating liquid 20 can be quickly supplied to contact portion 10C.

Preferably, conditions (amount of ejection, timing of ejection, and the like) under which control unit 7 causes ejection of insulating liquid 20, configurations of probe 1 and ejection nozzle 2a, and the like are employed such that insulating liquid 20 can be securely supplied to contact portion 10C at the same time as each of probes 1 and each of the electrodes are brought into contact with each other. In this way, insulating liquid 20 can be securely and quickly supplied to contact portion 10C. Accordingly, the measuring time concerned with the supply of insulating liquid 20 can be suppressed from being longer.

Further, in the measuring device according to the present embodiment, one or more probes 1 may be provided. For example, the measuring device may be configured to apply a voltage between one probe 1 and the surface of stage 9 and be capable of measuring electric current.

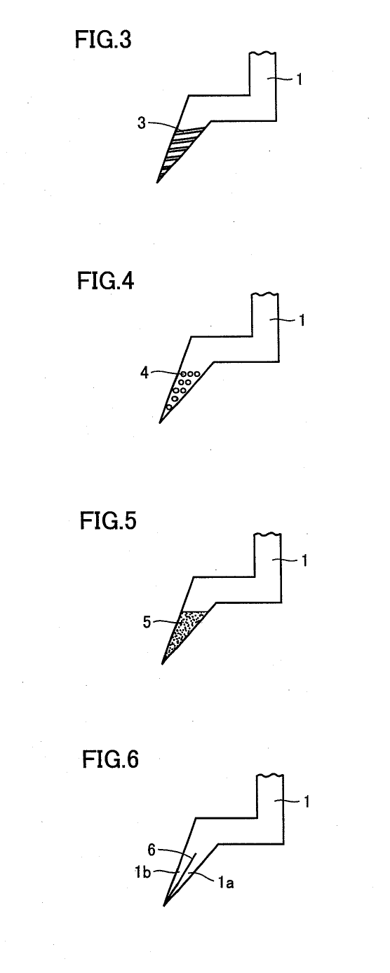

Further, in the measuring device according to the present embodiment, a retaining portion may be constructed in the surface of probe 1. The retaining portion is capable of retaining a predetermined amount of insulating liquid and is capable of supplying the insulating liquid to contact portion 10C between probe 1 and the electrode. Referring to FIG. 3, the retaining portion may be, for example, a groove 3 formed in the surface of probe 1. Groove 3 can be provided in any region of probe 1 as long as it does not affect the strength and contact resistance of probe 1. Groove 3 may be provided in the vicinity of the tip. For example, groove 3 may be formed to extend from the tip of probe 1 toward the root of probe 1 in the form of a straight line or a spiral. As a modification, referring to FIG. 4, the retaining portion may be holes 4 formed in the surface of probe 1. As another modification, referring to FIG. 5, the retaining portion may be irregularities 5 formed in the surface of probe 1. As still another modification, referring to FIG. 6, the retaining portion may be a cut groove 6 formed to separate the tip of probe 1 into a probe 1a and a probe 1b. When insulating liquid 20 supplied from ejection nozzle 2a to the surface of probe 1 reaches each of such retaining portions formed in probes 1, insulating liquid 20 is retained in the retaining portion. Also in each of these modifications, as with groove 3 described above, the retaining portion can be constructed in any region in the surface of probe 1.

Further, the measuring device according to the present embodiment may not be configured to be capable of applying a voltage between the plurality of probes 1. In this case, for example, each of probes 1 is grounded and a voltage is applied between probe 1 and stage 9.

Further, in the measuring device according to the present embodiment, supplying member 2 may be fixed to the base as long as the insulating liquid can be supplied to the surface of probe 1.

In the present embodiment, the element can be, for example, any semiconductor element called “power device”, and may be a MOSFET (Metal Oxide Semiconductor Field Effect Transistor).

### Second Embodiment

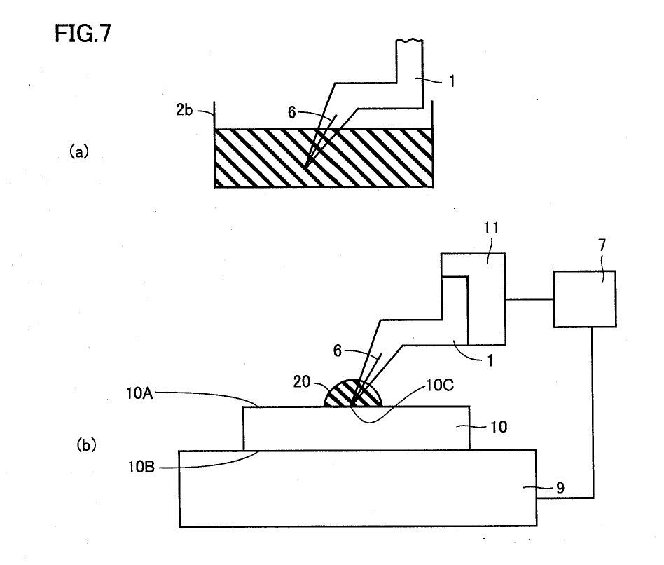

Referring to FIG. 7, the following describes a measuring device and a measuring method according to a second embodiment of the present invention. In the present embodiment, the measuring device and the measuring method are configured basically the same as the measuring device and the measuring method according to the first embodiment, but are different from the measuring device and the measuring method shown in FIG. 1 and FIG. 2 in the following points: supplying member 2 includes an insulating liquid bath 2b; and a retaining portion (cut groove 6 in the example of FIG. 7) is formed in the surface of probe 1 to temporarily retain the insulating liquid. It should be noted that in the present embodiment, the retaining portion is not limited to cut groove 6, and may be appropriately configured to be capable of temporarily retain the insulating liquid as described above.

In the present embodiment, the insulating liquid is not supplied from ejection nozzle 2a to the surface of probe 1. For example, referring to FIG. 7(a), the insulating liquid is supplied to the retaining portion formed in the surface of probe 1 by immersing probe 1 in insulating liquid bath 2b containing the insulating liquid and attached to the measuring device. Insulating liquid bath 2b may be, for example, attached to stage 9 and be movably provided. In this case, insulating liquid bath 2b may be moved to probe 1 fixed to the base as described above, so as to immerse probe 1 in insulating liquid bath 2b. Alternatively, insulating liquid bath 2b may be fixedly provided on the measuring device, for example. In this case, unlike the measuring device according to the first embodiment, probe 1 is movably provided, whereby probe 1 can be immersed in insulating liquid bath 2b.

In the measuring method according to the present embodiment, in order to supply the insulating liquid to the surface of probe 1, stage 9 or probe 1 movably provided needs to be moved. In doing so, probe 1 is immersed in insulating liquid bath 2b at a timing before an IGBT to be measured is moved to the measurement position, or at a timing before probe 1 is moved to the IGBT to be measured. Further, the timing at which probe 1 is immersed in insulating liquid bath 2b may repeatedly come at a certain interval during the measurement for the plurality of elements formed on wafer 10. Further, the measuring time can be suppressed from being longer due to the immersion of probe 1 in insulating liquid bath 2b, by appropriately configuring probe 1 or insulating liquid bath 2b, for example, by providing probe 1 with a retaining portion having a larger retention capacity, or by disposing a plurality of insulating liquid baths 2b around wafer 10. In this way, an effect similar to that in the measuring device according to the first embodiment can be obtained.

Further, in the measuring method according to the present embodiment, insulating liquid 20 can be supplied to contact portion 10C at the same time as probe 1 and the electrode are brought into contact with each other, thereby securely and quickly covering contact portion 10C.

The measuring device and the measuring method in the present invention can be applied particularly advantageously to a measuring device and a measuring method for a power element required to operate with a large current.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A measuring device comprising:
a probe applying a voltage to an electrode of an element; and
a supplying member supplying an insulating liquid to a contact portion between said electrode and said probe via a surface of said probe.

2. The measuring device according to claim 1, wherein said supplying member is attached to said probe, and includes an ejection nozzle ejecting said insulating liquid to said contact portion via the surface of said probe.

3. The measuring device according to claim 1, wherein
said supplying member includes a liquid bath containing said insulating liquid, and
said insulating liquid is supplied to said contact portion via the surface of said probe by immersing said probe in said liquid bath.

4. The measuring device according to claim 1, wherein said probe includes a retaining portion temporarily retaining said insulating liquid.

5. The measuring device according to claim 4, wherein said retaining portion is a groove formed in the surface of said probe.

6. The measuring device according to claim 4, wherein said retaining portion is a hole formed in the surface of said probe.

7. The measuring device according to claim 4, wherein said retaining portion is irregularities formed in the surface of said probe.

8. The measuring device according to claim 4, wherein said retaining portion is a cut groove formed in a tip of said probe.

9. A measuring method comprising the steps of:
preparing a wafer provided with an element including an electrode;
bringing said electrode of said element and a probe into contact with each other; and
measuring an element characteristic by flowing an electric current between said probe and said electrode with an insulating liquid being supplied to a contact portion between said electrode and said probe via a surface of said probe.

10. The measuring method according to claim 9, further comprising the step of supplying said insulating liquid to said contact portion between said electrode and said probe via the surface of said probe after the step of bringing and before the step of measuring.

11. The measuring method according to claim 9, further comprising the step of supplying said insulating liquid to the surface of said probe before the step of bringing.

12. The measuring method according to claim 9, wherein at the same time as the step of bringing is performed, said insulating liquid is supplied to said contact portion between said electrode and said probe via the surface of said probe.

13. The measuring method according to claim 9, wherein said probe includes a retaining portion temporarily retaining said insulating liquid.

14. The measuring method according to claim 13, wherein said retaining portion is a groove formed in the surface of said probe.

15. The measuring method according to claim 13, wherein said retaining portion is a hole formed in the surface of said probe.

16. The measuring method according to claim 13, wherein said retaining portion is irregularities formed in the surface of said probe.

17. The measuring method according to claim 13, wherein said retaining portion is a cut groove formed in a tip of said probe.

18. An element manufacturing method employing the measuring method recited in claim 9.
